(19) United States
(12) Patent Application Publication
(10) Pub. No.: US 2021/0255783 A1
(43) Pub. Date: Aug. 19, 2021

(54) METHOD AND APPARATUS FOR PERFORMING DATA STORAGE MANAGEMENT TO ENHANCE DATA RELIABILITY WITH AID OF REPEATED WRITE COMMAND DETECTION

(71) Applicant: Silicon Motion, Inc., Hsinchu County (TW)

(72) Inventors: Hsu-Ping Ou, Hsinchu County (TW); Meng-Hua Yang, Taoyuan City (TW)

(21) Appl. No.: 16/795,536

(22) Filed: Feb. 19, 2020

(51) Int. Cl. G06F 3/06; G11C 11/4074; G11C 11/56

(52) U.S. Cl. CPC G06F 3/0619; G06F 3/064; G06F 3/0644; G11C 2211/5641; G06F 3/0688; G11C 11/4074; G11C 11/5628; G06F 3/0659

(57) ABSTRACT

A method and apparatus for performing data storage management to enhance data reliability are provided. The method includes: receiving a write command from a host system, wherein the write command indicates that writing a set of data into a non-volatile (NV) memory is required; determining whether a repeated writing condition is satisfied, wherein the repeated writing condition includes the write command being a repeated write command of a previous write command and corresponding to a same address and a same length as that of the previous write command; and in response to the repeated writing condition being satisfied, storing the set of data into at least one of a first type of blocks within the NV memory, for performing data storage enhancement processing, wherein bit count per memory cell of the first type of blocks is less than bit count per memory cell of a second type of blocks.

### BACKGROUND OF THE INVENTION

### 1. Field of the Invention

The present invention is related to memory control, and more particularly, to a method and apparatus for performing data storage management to enhance data reliability, for example, with aid of repeated write command detection.

### 2. Description of the Prior Art

Developments in memory technology have led to the wide applications of portable or non-portable memory devices (e.g. a memory card conforming to the SD/MMC, CF, MS or XD specification, a solid-state drive (SSD), and an embedded memory device conforming to the UFS or eMMC specification). Thus, improving access control of memories in these memory devices remains an issue to be solved in the art.

NAND flash memories may typically comprise single level cell (SLC) and multiple level cell (MLC) flash memories. In an SLC flash memory, each transistor used as a memory cell may have any of two electrical charge values, respectively representing the logic values 0 and 1. In addition, the storage ability of each transistor used as a memory cell in an MLC flash memory may be fully utilized, where the transistor is driven by a voltage higher than that in the SLC flash memory, to record information of at least two bits (e.g. 00, 01, 11, or 10) in a transistor through different voltage levels. In theory, the recording density of the MLC flash memory may reach at least twice the recording density of the SLC flash memory, and is therefore preferred by manufacturers of NAND flash memories.

Compared with the SLC flash memory, the lower cost and larger capacity of the MLC flash memory means it is more likely to be applied in memory devices. The MLC flash memory does have instability issues, however. To ensure that access control of the flash memory in the memory device meets related specifications, a controller of the flash memory is usually configured to have management mechanisms to properly manage the access of data.

Related art memory devices with the above management mechanisms still have some disadvantages. For example, a host system such as a multifunctional mobile phone, a tablet, an all-in-one (AIO) computer, a laptop computer, etc. may store various kinds of user data of a user into a memory device therein. When it is needed that the memory device conforms to a certain specification, the memory device may merely perform some basic operations such as reading, writing, etc. as requested by the host system, and there may be no additional command for inter-device communications. As a result, the memory device may store the user data of the user in a data region of the memory device in a cost-effective manner by default, without any special treatment, since no additional command for inter-device communications is available. Thus, a novel method and associated architecture are needed for improving performance of memory devices without introducing any side effect or in a way that is less likely to introduce a side effect.

### SUMMARY OF THE INVENTION

It is therefore an objective of the present invention to provide a method for performing data storage management to enhance data reliability, for example, with aid of repeated write command detection, and to provide associated apparatus such as a memory device, a controller thereof, an electronic device comprising the memory device, etc., in order to solve the above-mentioned problems.

At least one embodiment of the present invention provides a method for performing data storage management to enhance data reliability, where the method may be applied to a memory device. The memory device may comprise a non-volatile (NV) memory, the NV memory may comprise at least one NV memory element (e.g. one or more NV memory elements), and the aforementioned at least one NV memory element may comprise a plurality of blocks. The method may comprise: receiving a write command from a host system, wherein the write command indicates that writing a set of data into the NV memory is required; determining whether a repeated writing condition is satisfied, wherein the repeated writing condition comprises the write command being a repeated write command of a previous write command and corresponding to a same address and a same length as that of the previous write command; and in response to the repeated writing condition being satisfied, storing the set of data into at least one first type block of a first type of blocks within the NV memory, for performing data storage enhancement processing, wherein a first bit count of one or more bits stored in a memory cell of any of the first type of blocks is less than a second bit count of multiple bits stored in a memory cell of any of a second type of blocks within the NV memory.

In addition to the above method, the present invention also provides a memory device, and the memory device comprises a NV memory and a controller. The NV memory is arranged to store information, wherein the NV memory may comprise at least one NV memory element (e.g. one or more NV memory elements), and the aforementioned at least one NV memory element may comprise a plurality of blocks. The controller is coupled to the NV memory, and the controller is arranged to control operations of the memory device. In addition, the controller comprises a processing circuit that is arranged to control the controller according to a plurality of host commands from a host system, to allow the host system to access the NV memory through the controller. For example, the controller receives a write command from the host system, wherein the write command indicates that writing a set of data into the NV memory is required; the controller determines whether a repeated writing condition is satisfied, wherein the repeated writing condition comprises the write command being a repeated write command of a previous write command and corresponding to a same address and a same length as that of the previous write command; and in response to the repeated writing condition being satisfied, the controller stores the set of data into at least one first type block of a first type of blocks within the NV memory, for performing data storage enhancement processing, wherein a first bit count of one or more bits stored in a memory cell of any of the first type of blocks is less than a second bit count of multiple bits stored in a memory cell of any of a second type of blocks within the NV memory.

According to some embodiments, an associated electronic device is also provided. The electronic device may comprise the above memory device, and may further comprise the host system. In addition, the host system may comprise a host device, and the host device may be coupled to the memory device. The host device may comprise: at least one processor, arranged for controlling operations of the host device; and a power supply circuit, coupled to the at least one processor, arranged for providing power to the at least one processor and the memory device. In addition, the memory device may provide the host device with storage space.

In addition to the above method, the present invention also provides a controller of a memory device, where the memory device comprises the controller and a NV memory. The NV memory may comprise at least one NV memory element (e.g. one or more NV memory elements), and the aforementioned at least one NV memory element may comprise a plurality of blocks. In addition, the controller comprises a processing circuit that is arranged to control the controller according to a plurality of host commands from a host system, to allow the host system to access the NV memory through the controller. For example, the controller receives a write command from the host system, wherein the write command indicates that writing a set of data into the NV memory is required; the controller determines whether a repeated writing condition is satisfied, wherein the repeated writing condition comprises the write command being a repeated write command of a previous write command and corresponding to a same address and a same length as that of the previous write command; and in response to the repeated writing condition being satisfied, the controller stores the set of data into at least one first type block of a first type of blocks within the NV memory, for performing data storage enhancement processing, wherein a first bit count of one or more bits stored in a memory cell of any of the first type of blocks is less than a second bit count of multiple bits stored in a memory cell of any of a second type of blocks within the NV memory.

The present invention method and associated apparatus can guarantee that the memory device can operate properly in various situations. With aid of the present invention method and associated apparatus, the memory device will not suffer from the existing problems of the related art. In addition, implementing the embodiments of the present invention will not greatly increase additional costs. Thus, problems existing in the related art can be solved without greatly increasing the overall cost. In comparison with the related art, the present invention can achieve optimal performance of memory devices without introducing side effects or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to an embodiment of the present invention.

FIG. 2 is a flowchart of a method for performing data storage management to enhance data reliability, for example, with aid of repeated write command detection, according to an embodiment of the present invention.

FIG. 3 illustrates a working flow of a data storage enhancement procedure involved with the method shown in FIG. 2 according to an embodiment of the present invention.

### DETAILED DESCRIPTION

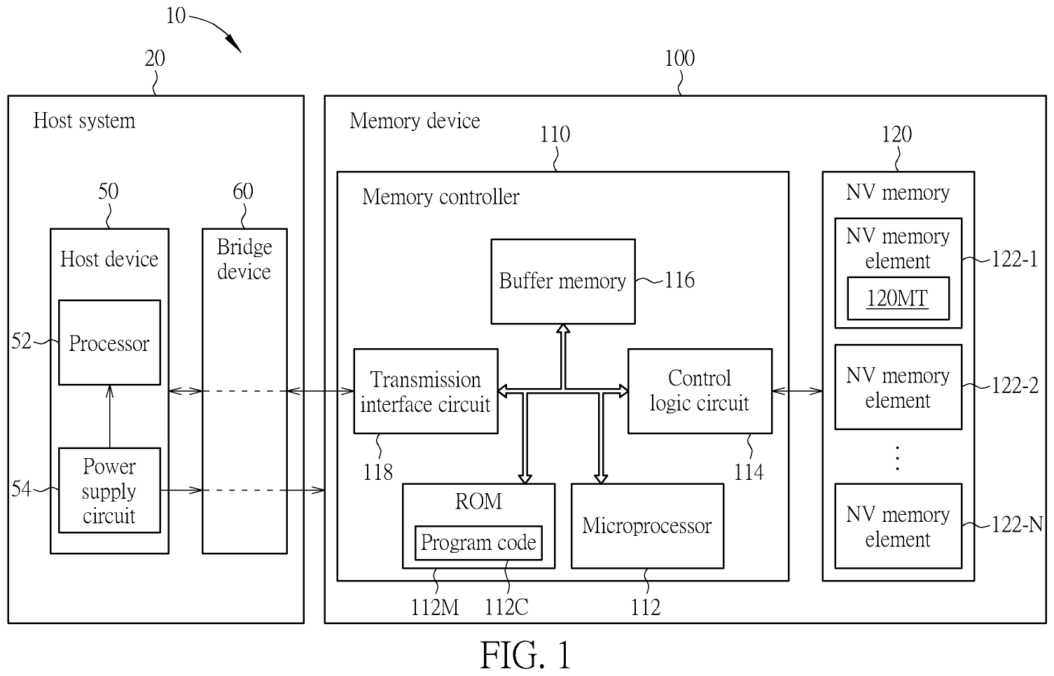

FIG. 1 is a diagram of an electronic device 10 according to an embodiment of the present invention, where the electronic device 10 comprises a host system 20 and a memory device 100, and the host system 20 comprises a host device 50 and a bridge device 60. The host device 50 may comprise at least one processor 52 (e.g. one or more processors) that is arranged to control operations of the host device 50, and may comprise a power supply circuit 54 that is coupled to the aforementioned at least one processor 52. The power supply circuit 54 may be arranged to provide the aforementioned at least one processor 52, the bridge device 60, and the memory device 100 with power, and more particularly, output at least one driving voltage to the bridge device 60 and provide one or more driving voltages to the memory device 100 through the bridge device 60 (e.g. output the one or more driving voltages to the memory device 100 through the bridge device 60, or utilize the bridge device 60 to regulate the aforementioned at least one driving voltage from the host device 50 to generate the one or more driving voltages, for being output to the memory device 100). Examples of the host device 50 may include, but are not limited to: a multifunctional mobile phone, a tablet computer, a wearable device, and a personal computer such as a desktop computer and a laptop computer. Examples of the memory device 100 may include, but are not limited to: a portable memory device (e.g. a memory card conforming to the SD/MMC, CF, MS or XD specification), a solid state drive (SSD), and various types of embedded memory devices (e.g. am embedded memory device conforming to the UFS or eMMC specification). Examples of the memory device 100 may include, but are not limited to: a memory card reader, a memory device adaptor, an interfacing circuit, etc. For better comprehension, the memory device 100 may provide the host device 50 with storage space, and may obtain the one or more driving voltages through the bridge device 60, to be the power of the memory device 100, but the present invention is not limited thereto. In some embodiments, the architecture shown in FIG. 1 may vary. For example, the bridge device 60 may be omitted or may be integrated into the host device 50. In this situation, the host system 20 may represent the host device 50.

According to this embodiment, the memory device 100 may comprise a controller such as a memory controller 110, and may further comprise a non-volatile (NV) memory 120, where the controller is arranged to access the NV memory 120, and the NV memory 120 is arranged to store information. The NV memory 120 may comprise at least one NV memory element (e.g. one or more NV memory elements), such as a plurality of NV memory elements 122-1, 122-2, . . . , and 122-N, where “N” may represent a positive integer that is greater than one. For example, the NV memory 120 may be a flash memory, and the plurality of NV memory elements 122-1, 122-2, . . . , and 122-N may be a plurality of flash memory chips (which may be referred to as flash chips) or a plurality of flash memory dies (which may be referred to as flash dies), respectively, but the present invention is not limited thereto. As shown in FIG. 1, the memory controller 110 may comprise a processing circuit such as a microprocessor 112, a storage unit such as a read only memory (ROM) 112M, a control logic circuit 114, a buffer memory 116, and a transmission interface circuit 118, where at least one portion (e.g. a portion or all) of the above components may be coupled to one another via a bus. The buffer memory 116 is implemented by a random access memory (RAM) (which may be a static RAM (SRAM), for example), where the RAM may be arranged to provide the memory controller 110 with internal storage space (for example, may temporarily store information), but the present invention is not limited thereto. In addition, the ROM 112M of this embodiment is arranged to store a program code 112C, and the microprocessor 112 is arranged to execute the program code 112C to control the access of the NV memory 120. Please note that, the program code 112C may also be stored in the buffer memory 116 or any type of memory. Additionally, the control logic circuit 114 may be arranged to control the NV memory 120. The control logic circuit 114 may comprise an error correction code (ECC) circuit (not shown in FIG. 1), which may perform ECC encoding and ECC decoding, to protect data, and/or perform error correction, and the transmission interface circuit 118 may conform to a specific communications specification (e.g. the Serial Advanced Technology Attachment (SATA) specification, Universal Serial Bus (USB) specification, Peripheral Component Interconnect Express (PCIE) specification, embedded Multi Media Card (eMMC) specification, or Universal Flash Storage (UFS) specification), and may perform communications according to the specific communications specification. For better comprehension, the bridge device 60 may be arranged to bridge the host device 50 and the memory device 100, for example, in a situation where the host device 50 conforms to another communications specification that differs from the specific communications specification, but the present invention is not limited thereto. In some examples, the host device 50 may also conform to the specific communications specification, and the bridge device 60 may bypass commands and data to the memory device 100 or bypass data to the host device 50.

In this embodiment, the host system 20 (more particularly, the host device 50, with aid of the bridge device 60) may transmit a plurality of host commands and corresponding logical addresses to the memory controller 110, to access the NV memory 120 within the memory device 100, indirectly. The memory controller 110 receives the plurality of host commands and the logical addresses, and translates the plurality of host commands into memory operating commands (which may be referred to as operating commands, for brevity), respectively, and further controls the NV memory 120 with the operating commands to perform reading or writing/programing upon the memory units (e.g. data pages) of specific physical addresses within the NV memory 120, where the physical addresses may be associated with the logical addresses. For example, the memory controller 110 may generate or update at least one logical-to-physical address mapping table to manage the relationship between the physical addresses and the logical addresses. The NV memory 120 may store a management table 120MT, for the memory controller 110 to control the memory device to manage blocks storing user data that has been processed with certain treatment. When there is a need, the memory controller 110 may load the management table 120MT into the buffer memory 116 or other memories. The management table 120MT may be positioned in a predetermined region within the NV memory element 122-1, such as a system region, but the present invention is not limited thereto. In some embodiments, the management table 120MT may be positioned in any of the NV memory elements 122-1, 122-2, . . . , and 122-N.

In addition, the aforementioned at least one NV memory element (e.g. the one or more NV memory elements such as {122-1, 122-2, . . . , 122-N}) may comprise a plurality of blocks, where the minimum unit that the memory controller 110 may perform operations of erasing data on the NV memory 120 may be a block, and the minimum unit that the memory controller 110 may perform operations of writing data on the NV memory 120 may be a page, but the present invention is not limited thereto. For example, any NV memory element 122-n within the NV memory elements 122-1, 122-2, . . . , and 122-N (where “n” may represent any integer in the interval [1,N]) may comprise a group of blocks, and a block within the group of blocks may comprise and record specific number of pages, where the memory controller 110 may access a certain page of a certain block within the group of blocks according to a block address and a page address. For another example, the NV memory element 122-n may comprise multiple planes, and any plane of the multiple planes may comprise a set of blocks such as the group of blocks, where the memory controller 110 may access a certain page of a certain block of a certain plane within the multiple planes according to a plane number, a block address and a page address.

Based on the architecture shown in FIG. 1, the memory device 100 (more particularly, the memory controller 110 therein) can operate properly in various situations to prevent existing problems of the related art, for example, in a situation where there is no additional command for inter-device communications between the host system 20 (e.g. a combination of the host device 50 and the bridge device 60, or the host device 50 for the case that the bridge device 60 may be omitted or may be integrated into the host device 50) and the memory device 100.

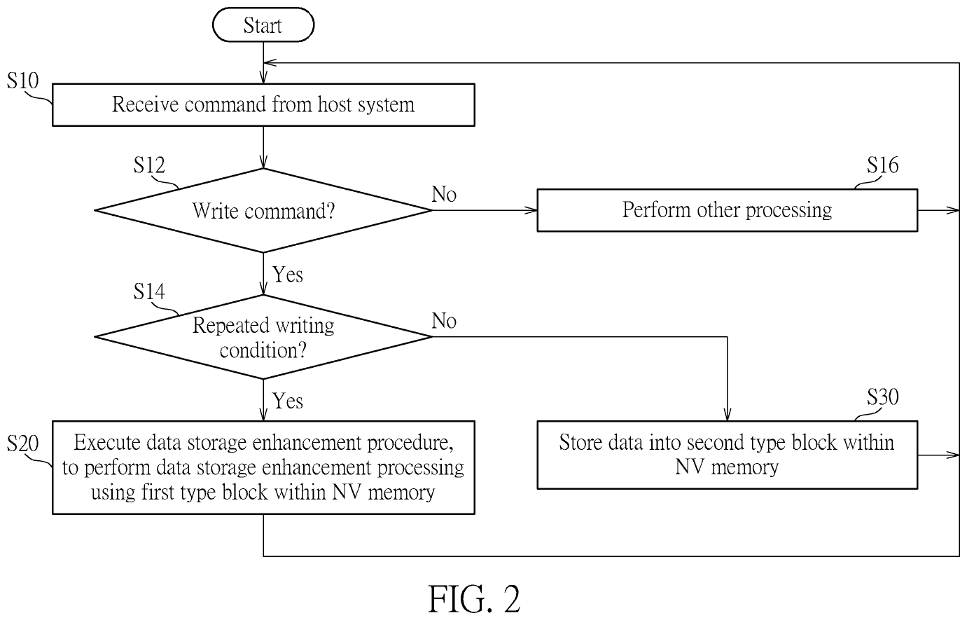

FIG. 2 is a flowchart of a method for performing data storage management to enhance data reliability, for example, with aid of repeated write command detection, according to an embodiment of the present invention. The method may be applied to the memory device 100 and the memory controller 110 therein, and may be applied to the electronic device 10 that comprises the host system 20 and the memory device 100.

In Step S10, the memory controller 110 may receive a command from the host system 20, such as one of the plurality of host commands.

In Step S12, the memory controller 110 may determine whether the command is a write command. If Yes, the memory controller 110 may execute Step S14; If No, the memory controller 110 may execute Step S16. For example, the command may represent the write command (e.g. the memory controller 110 may receive the write command from the host system 20 in Step S10), and the write command may indicate that writing a set of data into the NV memory 120 is required, but the present invention is not limited thereto. For another example, the command may represent a read command, and the read command may indicate that reading one or more sets of data from the NV memory 120 is required.

In Step S14, the memory controller 110 may determine whether a repeated writing condition is satisfied, where the repeated writing condition may comprise the write command being a repeated write command of a previous write command and corresponding to a same address and a same length as that of the previous write command. If Yes, the memory controller 110 may execute Step S20; If No, the memory controller 110 may execute Step S30. According to this embodiment, in a situation where the command mentioned in Step S10 represents the write command, the memory controller 110 may determine whether this write command is the next write command of the previous write command, and more particularly, may determine whether this write command indicates that writing data of the same length at the same address (e.g. the same logical address) is required. For example, when this write command is the next write command of the previous write command and indicates that writing data of the same length at the same address (e.g. the same logical address) is required, the memory controller 110 may determine that the repeated writing condition is satisfied, and therefore Step S20 is entered; otherwise, the memory controller 110 may determine that the repeated writing condition is not satisfied, and therefore Step S30 is entered; but the present invention is not limited thereto.

In Step S16, when the command is not the write command (e.g. the command may represent the read command), the memory controller 110 may perform other processing, rather than writing.

In Step S20, in response to the repeated writing condition being satisfied, the memory controller 110 may execute a data storage enhancement procedure, to perform data storage enhancement processing using at least one first type block of a first type of blocks within the NV memory 120. More particularly, a first bit count BITCNT(1) of one or more bits (e.g. BITCNT(1) bits) stored in a memory cell of any of the first type of blocks is less than a second bit count BITCNT(2) of multiple bits (e.g. BITCNT(2) bits) stored in a memory cell of any of a second type of blocks within the NV memory 120, and the reliability of the first type of blocks is greater than that of the second type of blocks. For example, the first type of blocks may comprise a group of single level cell (SLC) blocks, and the second type of blocks may comprise a group of triple level cell (TLC) blocks, where the first bit count BITCNT(1) and the second bit count BITCNT(2) may be equal to one and three, respectively, but the present invention is not limited thereto.

In Step S30, in response to the repeated writing condition being not satisfied, the memory controller 110 may store data (e.g. the set of data) into at least one second type block of the second type of blocks within the NV memory 120.

Based on the working flow shown in FIG. 2, the operation of Step S14 (e.g. the operation of determining whether the repeated writing condition is satisfied) may be executed multiple times to generate multiple determination results such as a first determination result and a second determination result, respectively, where the first determination result may indicate that the repeated writing condition is satisfied, and the second determination result may indicate that the repeated writing condition is not satisfied. For example, the operation of Step S20 (e.g. the operation of executing the data storage enhancement procedure to perform the data storage enhancement processing) may be executed in response to the first determination result. For another example, the operation of Step S30 (e.g. the operation of storing the set of data into the aforementioned at least one second type block of the second type of blocks within the NV memory 120) may be executed in response to the second determination result. Please note that, in a situation where the repeated writing condition mentioned in Step S14 is satisfied, the memory controller 110 may perform the data storage enhancement processing regarding the set of data during the data storage enhancement procedure mentioned in Step S20, to protect the set of data in the aforementioned at least one first type block of the first type of blocks with higher reliability.

For better comprehension, the method may be illustrated with the working flow shown in FIG. 2, but the present invention is not limited thereto. According to some embodiments, one or more steps may be added, deleted, or changed in the working flow shown in FIG. 2.

According to some embodiments, implementation of the first type of blocks and/or implementation of the second type of blocks may vary. For example, the first type of blocks may comprise the group of SLC blocks, and the second type of blocks may comprise a group of quadruple level cell (QLC) blocks, where the first bit count BITCNT(1) and the second bit count BITCNT(2) may be equal to one and four, respectively. For another example, the first type of blocks may comprise the group of SLC blocks, and the second type of blocks may comprise a group of multiple level cell (MLC) blocks, where the first bit count BITCNT(1) may be equal to one, and the second bit count BITCNT(2) may be equal to or greater than two (e.g. depending on different viewpoints regarding MLC). In some examples, the first type of blocks may comprise the group of SLC blocks, and the second type of blocks may comprise any group of multiple groups of higher level cell blocks, and the multiple groups of higher level cell blocks may comprise the group of MLC blocks, and more particularly, may comprise the group of TLC blocks, the group of QLC blocks, etc., where the first bit count BITCNT(1) may be equal to one, and the second bit count BITCNT(2) may be equal to the corresponding bit count selected from a sequence of {2, 3, 4, . . . }. In some other examples, the first type of blocks may comprise a first group in a series of groups comprising the group of SLC blocks, the group of MLC blocks, the group of TLC blocks, the group of QLC blocks, etc., and the second type of blocks may comprise a second group in the series of groups, such as one of the subsequent groups coming after the first group in the series of groups, where the first bit count BITCNT(1) may be equal to a certain bit count selected from a sequence {1, 2, 3, 4, . . . } corresponding to the series of groups, and the second bit count BITCNT(2) may be equal to another bit count selected from the sequence {1, 2, 3, 4, . . . } and is greater than the first bit count BITCNT(1).

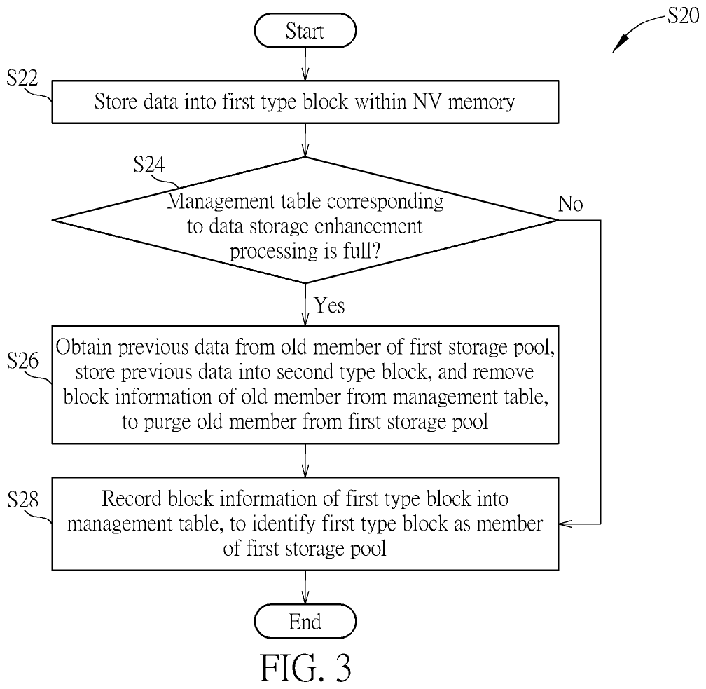

FIG. 3 illustrates a working flow of the data storage enhancement procedure involved with the method shown in FIG. 2 according to an embodiment of the present invention.

In Step S22, in response to the repeated writing condition being satisfied, the memory controller 110 may store the set of data into the aforementioned at least one first type block of the first type of blocks within the NV memory 120, for performing the data storage enhancement processing. For example, the operation of Step S22 may be executed in response to the first determination result.

In Step S24, the memory controller 110 may determine whether the management table 120MT corresponding to the data storage enhancement processing is full, for managing a first storage pool within the NV memory 120 for the data storage enhancement processing, where the first storage pool may comprise at least one portion (e.g. a portion or all) of the first type of blocks within the NV memory 120, and table contents of the management table 120MT may correspond to the aforementioned at least one portion of the first type of blocks, and more particularly, may represent the aforementioned at least one portion of the first type of blocks, but the present invention is not limited thereto. If Yes, the memory controller 110 may execute Step S26; If No, the memory controller 110 may execute Step S28.

In Step S26, in response to the management table 120MT being full, the memory controller 110 may obtain at least one set of previous data (e.g. one or more sets of previous data) from one or more old members of the first storage pool, store the aforementioned at least one set of previous data into one or more second type blocks of the second type of blocks, and remove block information (e.g. one or more physical addresses) of the one or more old members from the management table 120MT, to purge the one or more old members from the first storage pool, where the one or more old members may represent one or more first type blocks of the first type of blocks.

In Step S28, the memory controller 110 may record block information (e.g. at least one physical address) of the aforementioned at least one first type block of the first type of blocks into the management table 120MT, to identify the aforementioned at least one first type block of the first type of blocks as at least one member of the first storage pool.

Based on the working flow shown in FIG. 3, the operation of Step S24 (e.g. the operation of determining whether the management table 120MT corresponding to the data storage enhancement processing is full) may be executed multiple times to generate multiple determination results such as a third determination result and a fourth determination result, respectively, where the third determination result may indicate that the management table 120MT is full, and the fourth determination result may indicate that the management table 120MT is not full. For example, the operations of Step S26 (e.g. the operations of obtaining the aforementioned at least one set of previous data from the one or more old members of the first storage pool, storing the aforementioned at least one set of previous data into the one or more second type blocks of the second type of blocks, and removing the block information of the one or more old members from the management table 120MT) may be executed in response to the third determination result. For another example, the operation of Step S28 (e.g. the operation of recording the block information of the aforementioned at least one first type block of the first type of blocks into the management table 120MT) may be executed in response to the fourth determination result. Please note that, no matter whether the management table 120MT mentioned in Step S24 is full or is not full, the memory controller 110 may record the block information of the aforementioned at least one first type block of the first type of blocks into the management table 120MT in Step S28, to add the aforementioned at least one first type block of the first type of blocks into the first storage pool, where the memory controller 110 may store the set of data into the aforementioned at least one first type block of the first type of blocks with higher reliability to protect the set of data. As a result, the table contents of the management table 120MT may indicate that data stored in the aforementioned at least one portion of the first type of blocks is protected by the data storage enhancement processing.

For better comprehension, the method (more particularly, the data storage enhancement procedure) may be illustrated with the working flow shown in FIG. 3, but the present invention is not limited thereto. According to some embodiments, one or more steps may be added, deleted, or changed in the working flow shown in FIG. 3.

According to some embodiments, the memory controller 110 may utilize the first block pool corresponding to the first type of blocks (e.g. an SLC pool corresponding to the group of SLC blocks) to perform the data storage enhancement processing mentioned in Step S20, where data stored in any block of the first block pool is protected by the data storage enhancement processing, and data stored in any block of a second block pool corresponding to the second type of blocks (e.g. a TLC pool corresponding to the group of TLC blocks, a QLC pool corresponding to the group of QLC blocks, etc.) is not protected by the data storage enhancement processing, but the present invention is not limited thereto.

Some implementation details regarding the repeated writing condition mentioned in Step S14 may be described as follows. According to some embodiments, in a situation where the command mentioned in Step S10 represents the write command and Steps S12 and S14 are entered subsequently, the memory controller 110 may perform an additional check regarding the set of data to guarantee the correctness of the operation of Step S14. In Step S14, the memory controller 110 may further perform a repeated data detection regarding the set of data to generate a repeated data detection result, where the repeated data detection result may indicate whether this set of data to be written as requested by this write command is the same as previously written data such as the data that has been written as requested by the previous write command. For example, when this write command is the next write command of the previous write command and indicates that writing data (e.g. the set of data) of the same length at the same address (e.g. the same logical address) is required, and the repeated data detection result indicates that this set of data to be written as requested by this write command is the same as the previously written data (e.g. the data that has been written as requested by the previous write command), the memory controller 110 may determine that the repeated writing condition is satisfied, and therefore Step S20 is entered; otherwise, the memory controller 110 may determine that the repeated writing condition is not satisfied, and therefore Step S30 is entered. As a result, the repeated writing condition may further comprise the repeated data detection result indicating that this set of data to be written as requested by this write command is the same as the previously written data (e.g. the data that has been written as requested by the previous write command).

According to some embodiments, performing the repeated data detection may be implemented by detecting characteristic information of the set of data, such as a cyclic redundancy check (CRC) code, a hash value, etc. of the set of data. More particularly, during performing the repeated data detection, the memory controller 110 may detect the characteristic information of the set of data (e.g. the CRC code, the hash value, etc. thereof), and compare the characteristic information of the set of data with previous characteristic information to determine whether the characteristic information of the set of data is the same as the previous characteristic information, to generate the repeated data detection result. For example, the memory controller 110 may temporarily store characteristic information of the previously written data (e.g. a CRC code, a hash value, etc. of the data of the previous write command) in the buffer memory 116 in advance to be the previous characteristic information, but the present invention is not limited thereto. For another example, the memory controller 110 may temporarily store the characteristic information of the previously written data (e.g. the CRC code, the hash value, etc. of the data of the previous write command) in any other memory of the memory device 100 to be the previous characteristic information. For yet another example, the memory controller 110 may read the characteristic information of the previously written data (e.g. the CRC code, the hash value, etc. of the data of the previous write command) from the NV memory 120 to be the previous characteristic information.

According to some embodiments, the memory controller 110 may calculate the characteristic information of the set of data (e.g. the CRC code, the hash value, etc. thereof) and the previous characteristic information (e.g. the CRC code, the hash value, etc. of the data of the previous write command) by itself, but the present invention is not limited thereto. In some embodiments, the host system 20 (e.g. the host device 50) may calculate the characteristic information of the set of data (e.g. the CRC code, the hash value, etc. thereof) and the previous characteristic information (e.g. the CRC code, the hash value, etc. of the data of the previous write command) in advance and send them to the memory device 100, for example, to be attached information of the respective data, and therefore, the memory controller 110 may obtain the characteristic information of the set of data and the previous characteristic information.

According to some embodiments, performing the repeated data detection may be implemented by comparing the set of data with the previously written data. For example, the memory controller 110 may compare the set of data to be written as requested by the write command (e.g. the current write command) with the previously written data, where the previously written data may be still buffered in a certain buffer of the memory device 100, where this buffer may be implemented with an external memory of the memory controller 110, such as a dynamic RAM (DRAM) in the memory device 100, but the present invention is not limited thereto.

Those skilled in the art will readily observe that numerous modifications and alterations of the device and method may be made while retaining the teachings of the invention. Accordingly, the above disclosure should be construed as limited only by the metes and bounds of the appended claims.

1. A method for performing data storage management to enhance data reliability, the method being applied to a memory device, the memory device comprising a non-volatile (NV) memory, the NV memory comprising at least one NV memory element, said at least one NV memory element comprising a plurality of blocks, the method comprising:
receiving a write command from a host system, wherein the write command indicates that writing a set of data into the NV memory is required;
determining whether a repeated writing condition is satisfied, wherein the repeated writing condition comprises the write command being a repeated write command of a previous write command and corresponding to a same address and a same length as that of the previous write command; and
in response to the repeated writing condition being satisfied, storing the set of data, the set of data being a same set of data required to be written as indicated by a same write command which is said write command, into at least one first type block of a first type of blocks within the NV memory, for performing data storage enhancement processing, wherein a first bit count of one or more bits stored in a memory cell of any of the first type of blocks is less than a second bit count of multiple bits stored in a memory cell of any of a second type of blocks within the NV memory.

2. The method of claim 1, wherein the step of determining whether the repeated writing condition is satisfied is executed multiple times to generate a first determination result and a second determination result, respectively, wherein the first determination result indicates that the repeated writing condition is satisfied, and the second determination result indicates that the repeated writing condition is not satisfied; the step of storing the set of data into said at least one first type block of the first type of blocks within the NV memory is executed in response to the first determination result; and the method further comprises:
in response to the second determination result, storing the set of data into at least one second type block of the second type of blocks within the NV memory.

3. The method of claim 1, further comprising:
after the step of storing the set of data into said at least one first type block of the first type of blocks within the NV memory is executed, determining whether a management table corresponding to the data storage enhancement processing is full, for managing a first storage pool within the NV memory for the data storage enhancement processing, wherein the first storage pool comprises at least one portion of the first type of blocks within the NV memory, and table contents of the management table correspond to said at least one portion of the first type of blocks.

4. The method of claim 3, further comprising:
in response to the management table being not full, recording block information of said at least one first type block of the first type of blocks into the management table, to identify said at least one first type block of the first type of blocks as at least one member of the first storage pool.

5. The method of claim 3, further comprising:
in response to the management table being full, obtaining at least one set of previous data from one or more old members of the first storage pool, storing said at least one set of previous data into one or more second type blocks of the second type of blocks, and removing block information of the one or more old members from the management table, to purge the one or more old members from the first storage pool, wherein the one or more old members represent one or more first type blocks of the first type of blocks.

6. The method of claim 5, further comprising:
recording block information of said at least one first type block of the first type of blocks into the management table, to identify said at least one first type block of the first type of blocks as at least one member of the first storage pool.

7. The method of claim 3, wherein the table contents of the management table indicate that data stored in said at least one portion of the first type of blocks is protected by the data storage enhancement processing.

8. The method of claim 1, wherein the first type of blocks comprise a group of single level cell (SLC) blocks.

9. The method of claim 8, wherein the second type of blocks comprise any group of multiple groups of higher level cell blocks, and the multiple groups of higher level cell blocks comprise a group of triple level cell (TLC) blocks and a group of quadruple level cell (QLC) blocks.

10. The method of claim 1, further comprising:
utilizing a first block pool corresponding to the first type of blocks to perform the data storage enhancement processing, wherein data stored in any block of the first block pool is protected by the data storage enhancement processing, and data stored in any block of a second block pool corresponding to the second type of blocks is not protected by the data storage enhancement processing.

11. A memory device, comprising:
a non-volatile (NV) memory, arranged to store information, wherein the NV memory comprises at least one NV memory element, and said at least one NV memory element comprises a plurality of blocks; and
a controller, coupled to the NV memory, arranged to control operations of the memory device, wherein the controller comprises:
a processing circuit, arranged to control the controller according to a plurality of host commands from a host system, to allow the host system to access the NV memory through the controller,
wherein:
the controller receives a write command from the host system, wherein the write command indicates that writing a set of data into the NV memory is required;
the controller determines whether a repeated writing condition is satisfied, wherein the repeated writing condition comprises the write command being a repeated write command of a previous write command and corresponding to a same address and a same length as that of the previous write command; and
in response to the repeated writing condition being satisfied, the controller stores the set of data, the set of data being a same set of data required to be written as indicated by a same write command which is said write command, into at least one first type block of a first type of blocks within the NV memory, for performing data storage enhancement processing, wherein a first bit count of one or more bits stored in a memory cell of any of the first type of blocks is less than a second bit count of multiple bits stored in a memory cell of any of a second type of blocks within the NV memory.

12. The memory device of claim 11, wherein the operation of determining whether the repeated writing condition is satisfied is executed multiple times to generate a first determination result and a second determination result, respectively, wherein the first determination result indicates that the repeated writing condition is satisfied, and the second determination result indicates that the repeated writing condition is not satisfied; the operation of storing the set of data into said at least one first type block of the first type of blocks within the NV memory is executed in response to the first determination result; and in response to the second determination result, the controller stores the set of data into at least one second type block of the second type of blocks within the NV memory.

13. The memory device of claim 11, wherein after the operation of storing the set of data into said at least one first type block of the first type of blocks within the NV memory is executed, the controller determines whether a management table corresponding to the data storage enhancement processing is full, for managing a first storage pool within the NV memory for the data storage enhancement processing, wherein the first storage pool comprises at least one portion of the first type of blocks within the NV memory, and table contents of the management table correspond to said at least one portion of the first type of blocks.

14. The memory device of claim 13, wherein in response to the management table being not full, the controller records block information of said at least one first type block of the first type of blocks into the management table, to identify said at least one first type block of the first type of blocks as at least one member of the first storage pool.

15. The memory device of claim 13, wherein in response to the management table being full, the controller obtains at least one set of previous data from one or more old members of the first storage pool, storing said at least one set of previous data into one or more second type blocks of the second type of blocks, and removing block information of the one or more old members from the management table, to purge the one or more old members from the first storage pool, wherein the one or more old members represent one or more first type blocks of the first type of blocks.

16. The memory device of claim 15, wherein the controller records block information of said at least one first type block of the first type of blocks into the management table, to identify said at least one first type block of the first type of blocks as at least one member of the first storage pool.

17. The memory device of claim 13, wherein the table contents of the management table indicate that data stored in said at least one portion of the first type of blocks is protected by the data storage enhancement processing.

18. The memory device of claim 11, wherein the first type of blocks comprise a group of single level cell (SLC) blocks.

19. An electronic device comprising the memory device of claim 11, and further comprising:
the host system, comprising:
a host device, coupled to the memory device, wherein the host device comprises:
at least one processor, arranged for controlling operations of the host device; and
a power supply circuit, coupled to the at least one processor, arranged for providing power to the at least one processor and the memory device;
wherein the memory device provides the host device with storage space.

20. A controller of a memory device, the memory device comprising the controller and a non-volatile (NV) memory, the NV memory comprising at least one NV memory element, said at least one NV memory element comprising a plurality of blocks, the controller comprising:
a processing circuit, arranged to control the controller according to a plurality of host commands from a host system, to allow the host system to access the NV memory through the controller, wherein:
the controller receives a write command from the host system, wherein the write command indicates that writing a set of data into the NV memory is required;
the controller determines whether a repeated writing condition is satisfied, wherein the repeated writing condition comprises the write command being a repeated write command of a previous write command and corresponding to a same address and a same length as that of the previous write command; and
in response to the repeated writing condition being satisfied, the controller stores the set of data, the set of data being a same set of data required to be written as indicated by a same write command which is said write command, into at least one first type block of a first type of blocks within the NV memory, for performing data storage enhancement processing, wherein a first bit count of one or more bits stored in a memory cell of any of the first type of blocks is less than a second bit count of multiple bits stored in a memory cell of any of a second type of blocks within the NV memory.
